(19) United States
(12) Patent Application Publication
(10) Pub. No.: US 2020/0096535 A1
(43) Pub. Date: Mar. 26, 2020

(54) CHARGE OUTPUT STRUCTURE AND PIEZOELECTRIC ACCELERATION SENSOR THEREOF

(71) Applicant: FATRI United Testing & Control (Quanzhou) Technologies Co., Ltd., Quanzhou City (CN)

(72) Inventors: Nie Yongzhong, Quanzhou City (CN); Fu Zhihua, Quanzhou City (CN); Nie Chuan, Quanzhou City (CN); Zeng Tingfang, Quanzhou City (CN)

(21) Appl. No.: 16/400,129

(22) Filed: May 1, 2019

(30) Foreign Application Priority Data
Sep. 20, 2018 (CN) 201811103741.7

(51) Int. Cl. G01P 15/09; H01L 41/113; H01L 41/083

(52) U.S. Cl. CPC G01P 15/09; H01L 41/083; H01L 41/1132

(57) ABSTRACT

The present application refers to the field of sensors, and in particular to a charge output structure, comprising a base, having an insulating member, a piezoelectric element and a mass block successively arranged from inside to outside and radially sleeved thereon; and a pretightening member, sleeved on an outer periphery of the mass block and having an annular structure capable of applying a radial pretightening force to the insulating member, the piezoelectric element and the mass block through shrinking with rise of temperature. Also provided is a piezoelectric acceleration sensor having the above charge output structure. The present application greatly enhances the contact stiffness of the whole structure, thereby achieves better frequency response and resonance of the whole structure.

### CROSS REFERENCE TO RELATED APPLICATIONS

This application claims priority to Chinese Patent Application No. 201811103741.7, filed on Sep. 20, 2018, the entire contents of which are incorporated herein by reference.

### TECHNICAL FIELD

The present application refers to the field of sensors, and in particular to a charge output structure and piezoelectric acceleration sensor thereof.

### BACKGROUND

The signal output by a piezoelectric acceleration sensor is proportional to the vibration acceleration of a system. The main problem is that use of different materials for assembling causes insufficiency of the global contact stiffness, thus resulting in low frequency response and low resonance. In order to ensure a firm assembling using different materials, currently, a widely used design is to use an epoxy adhesive bonding, which solves the problem of the bonding of different materials, but proposes high requirements for the quality of the epoxy adhesives between the bonding layers and the operation. If the epoxy adhesives contain impurities or bubbles are generated due to the operation, the global stiffness of the products may become insufficient, which reduces the global stiffness of the sensor. Since the adhesive process requires a long time of baking, the temperature of the piezoelectric acceleration sensor may become high, which affects the frequency response characteristics.

### SUMMARY

Therefore, the technical problem to be solved by the present application is to overcome the defects of insufficiency of the global stiffness of the product in the prior art, which affect the frequency response characteristics, thereby providing a charge output structure with high global stiffness and good frequency response and resonance, and a piezoelectric acceleration sensor thereof.

In order to solve the above technical problem, the present application provides a charge output structure, comprising a base, having an insulating member, a piezoelectric element and a mass block successively arranged from inside to outside and radially sleeved thereon; and a pretightening member, sleeved on an outer periphery of the mass block and having an annular structure capable of applying a radial pretightening force to the insulating member, the piezoelectric element and the mass block through shrinking with rise of temperature.

Further, the pretightening member is made of nickel-titanium memory alloy.

Further, the piezoelectric element comprises an electrode sheet disposed adjacent to the insulating member and a piezoelectric crystal disposed adjacent to the mass block.

Further, the base comprises a supporting member and a connecting member disposed on the supporting member; the insulating member, the electrode sheet, the piezoelectric crystal, the mass block and the pretightening member are sleeved on the connecting member, and a gap is reserved between the insulating member, the electrode sheet, the piezoelectric crystal, the mass block and the pretightening member and the supporting member.

Further, the piezoelectric element and the mass block are both annular structures formed by a plurality of monomers connected together, and the number of the monomers is the integral multiple of 4.

Further, the monomer of the mass block is a sector-shaped monomer, four sector-shaped monomers are symmetrically distributed and sequentially connected to form an annular structure; the monomer of the piezoelectric element is a rectangular monomer, and four rectangular monomers are symmetrically distributed and sequentially connected to form an annular structure.

Further, the mass block and the piezoelectric crystal have a groove disposed on a contact surface thereof, and the piezoelectric crystal is embedded in the groove.

Further, a projection for connecting two adjacent electrode sheets is disposed on the electrode sheets.

Further, the mass block is made of stainless steel or tungsten-copper alloy.

Also provided is a piezoelectric acceleration sensor, comprising a charge output structure, further comprising a circuit board; the circuit board is electrically connected to the piezoelectric element.

Further, both of the charge output structure and the circuit board are disposed in the housing, and have a predetermined distance from the piezoelectric element.

1. In the charge output structure provided by the present application, the insulating member, the piezoelectric element and the mass block are successively arranged from inside to outside and radially sleeved on the base, the pretightening member is sleeved on the outer periphery of the mass block, and is an annular structure having a capacity of shrinking with rise of temperature to apply a radial pretightening force to the insulating member, the piezoelectric element and the mass block arranged inside the pretightening member when the pretightening member is heated to a certain temperature in the assembling process. Since the connection between the structural members is rigid, the application of the pretightening force greatly improves contact stiffness of the whole structure, and eliminates the influence of the adhesive intermediate layer on the contact surface, and achieves better frequency response and resonance of the whole structure, and solves the problem that the frequency response characteristics are affected due to the insufficient global stiffness of the product.

2. In the charge output structure provided by the present application, the pretightening member is made of nickel-titanium memory alloy. The nickel-titanium memory alloy itself has properties such as high fatigue strength, high damping characteristics, and shrinking with rise of temperature, wear resistance, corrosion resistance, high damping and super elasticity, thus providing the possibility of applying a pretightening force.

3. In the charge output structure provided by the present application, the piezoelectric element and the mass block are both annular structures formed by a plurality of monomers connected together, and the number of the monomers is the integral multiple of 4. The piezoelectric element and the mass block are designed with a four-sided shear symmetrical structure, which have greater charge output than the integral structure of the prior art, and satisfy higher requirements for use.

4. In the charge output structure provided by the present application, the mass block and the piezoelectric crystal have a groove disposed on a contact surface thereof, and the piezoelectric crystal is embedded in the groove. The groove is provided on the bottom surface of the mass block to directly fix the piezoelectric crystal for easy installation.

### BRIEF DESCRIPTION OF THE DRAWING

One or more embodiments are illustrated by way of example, and not by limitation, in the figures of the accompanying drawings, wherein elements having the same reference numeral designations represent like elements throughout. The drawings are not to scale, unless otherwise disclosed.

In order to more clearly illustrate the technical solutions of the embodiments of the present application or the prior art, the drawings used in the embodiments of the present application or the prior art will be briefly described below. Obviously, the drawings in the following description are only some embodiments of the present application, and those skilled in the art can obtain other drawings based on these drawings without any creative efforts.

FIG. 1 is cross-sectional view showing the overall assembly of the piezoelectric acceleration sensor provided by the present application;

FIG. 2 is a sectional view of the piezoelectric acceleration sensor provided by the present application;

FIG. 3 is a top view of FIG. 2 including the housing;

FIG. 4 is a schematic view of the pretightening member of FIG. 1;

FIG. 5 is a schematic view of the electrode sheet of FIG. 1;

FIG. 6 is a schematic view of FIG. 2 including a mounting fixture;

FIG. 7 is top view of FIG. 2 including a top alignment fixture.

In the drawings:

1-upper cover, 2-housing, 3-insulating member, 4-electrode sheet, 5-piezoelectric crystal, 6-mass block, 7-pretightening member, 8-base, 9-circuit board, 10-supporting member, 11-connecting member, 12-alignment fixture, 13-bottom fixture, 14-top alignment fixture.

### DETAILED DESCRIPTION

The technical solutions of the present application will be described clearly and completely with reference to the accompanying drawings. It is obvious that the described embodiments are only a part of the embodiments of the present application, and not all of the embodiments. All other embodiments obtained by those skilled in the art based on the embodiments of the present application without any creative efforts are within the scope of the present application.

Further, the technical features involved in the different embodiments of the present application described below may be combined with each other as long as a conflict is constituted.

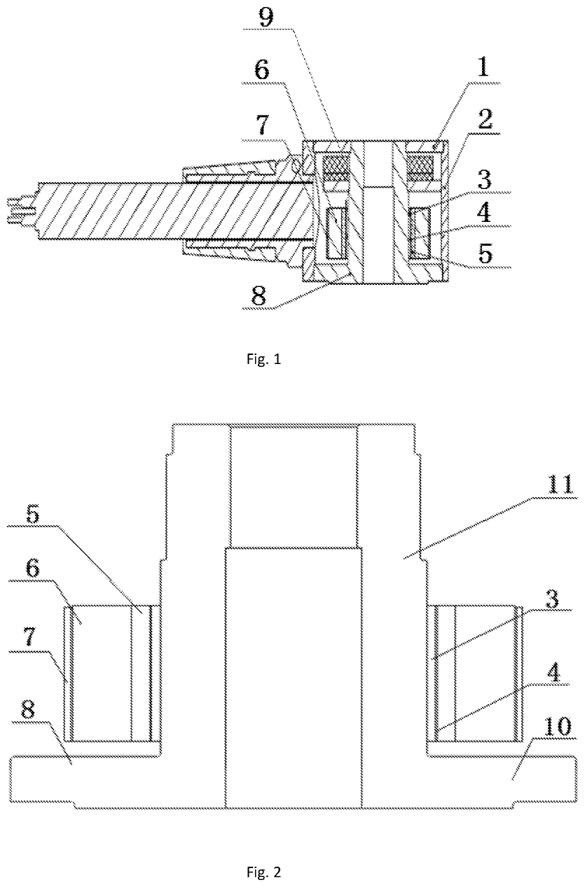

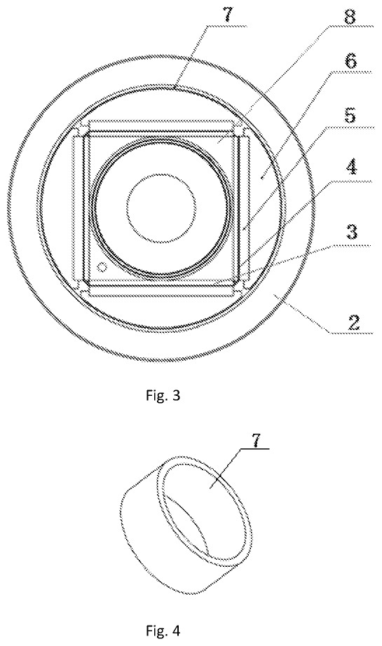

In an embodiment shown in FIGS. 2-5, a charge output structure comprises a base 8, having an insulating member 3, a piezoelectric element and a mass block 6 successively arranged from inside to outside and radially sleeved thereon; and a pretightening member 7, sleeved on an outer periphery of the mass block 6 and having an annular structure capable of applying a radial pretightening force to the insulating member 3, the piezoelectric element and the mass block 6 through shrinking with rise of temperature.

In the above charge output structure, the insulating member 3, the piezoelectric element and the mass block 6 are both an annular structure, and successively arranged from inside to outside and radially sleeved on the base 8, the pretightening member 7 is sleeved on the outer periphery of the mass block 6, and is an annular structure having a capacity of shrinking with rise of temperature to apply a radial pretightening force to the insulating member 3, the piezoelectric element and the mass block 6 arranged inside the pretightening member 7 when the pretightening member 7 is heated to a certain temperature. Since no connection layer and adhesive is formed between the members, the rigid connection between the structural members can be ensured, which enhances the pretightening force between the structural members in the assembling process, greatly enhances contact stiffness of the whole structure, and achieves better frequency response and resonance of the whole structure.

The pretightening member 7 is made of nickel-titanium memory alloy. The nickel-titanium memory alloy itself has properties such as high fatigue strength, high damping characteristics, capability of shrinking with rise of temperature, wear resistance, corrosion resistance, high damping and super elasticity.

The piezoelectric element comprises an electrode sheet 4 disposed adjacent to the insulating member 3 and a piezoelectric crystal 5 disposed adjacent to the mass block 6. The piezoelectric element comprises an electrode sheet 4 and a piezoelectric crystal 5, i.e. the base 8, the insulating member 3, the electrode sheet 4 and the piezoelectric crystal 5 and the mass block 6 are successively arranged from inside to outside, and the insulating member 3 isolates the piezoelectric crystal 5 from the base 8 to achieve the effect of the insulation of a signal ground from the tested mounting surface.

The base 8 comprises a supporting member 10 and a connecting member 11 disposed on the supporting member 10. The supporting member 10 is a disc-shaped base. The connecting member 11 is a cylinder integrally formed with the support member 10 and located at the center of the supporting member 10. The cylinder is hollow inside for easy installation. The insulating member 3, the electrode sheet 4, the piezoelectric crystal 5, the mass block 6 and the pretightening member 7 are sleeved on the connecting member 11, and a gap is reserved between the insulating member 3, the electrode sheet 4, the piezoelectric crystal 5, the mass block 6 and the pretightening member 7 and the supporting member 10. During installation, the insulating member 3, the electrode sheet 4, the piezoelectric crystal 5, the mass block 6 and the pretightening member 7 are successively sleeved on the connecting member 11, and a gap is reserved between the insulating member 3, the electrode sheet 4, the piezoelectric crystal 5, the mass block 6 and the pretightening member 7 and the supporting member 10, so as to a certain vibration gap for the charge output structure is reserved when in use to avoid damage to the insulating member 3, the electrode sheet 4, and the piezoelectric crystal, the mass block 6 and the pretightening member 7 due to excessive vibration.

The piezoelectric element and the mass block 6 are both annular structures formed by a plurality of monomers connected together, and the number of the monomers is the integral multiple of 4. The piezoelectric element and the mass block 6 are single monomers, and are annular structures formed in a four-sided shear symmetrical form, which can greatly increase the sensitivity and save space.

Specifically, the monomer of the mass block 6 is a sector-shaped monomer, four sector-shaped monomers are symmetrically distributed and sequentially connected to form an annular structure; the monomer of the piezoelectric element is a rectangular monomer, and four rectangular monomers are symmetrically distributed and sequentially connected to form an annular structure. The monomer of the mass block 6 is designed to be a fan-shaped monomer to cooperate with the annular structure of the pretightening member 7, so that the mass block 6 can be installed in the pretightening member 7. The monomer of the piezoelectric element is designed to be a rectangular monomer to fit with the mass block 6 closely and be easy to process. The mass block 6 and the piezoelectric crystal have simple structures, are easy to process and suitable for mass production.

As shown in FIG. 2, the mass block 6 and the piezoelectric crystal 5 have a groove disposed on a contact surface thereof, and the piezoelectric crystal 5 is embedded in the groove. The mass block 6 and the piezoelectric crystal 5 have a groove matching the piezoelectric crystal 5 disposed on a contact surface thereof, i.e. the width of the groove is equal to the length of the rectangular piezoelectric crystal 5. The piezoelectric crystal 5 can be directly fixed by a tight fit. The mass block 6 limits the position of the piezoelectric crystal 5.

As a specific embodiment, as shown in FIG. 5, a projection for connecting two adjacent electrode sheets 4 is disposed on the electrode sheets 4. Two protrusions are symmetrically disposed on the electrode sheet 4, and are disposed on the upper and lower portions of the electrode sheet 4. The plurality of electrode sheets 4 are connected end to end to form an annular structure, which realizes the parallel connection of the piezoelectric crystals 5, and enhances the conductivity and sensitivity of the charge output structure.

The mass block 6 is made of stainless steel or tungsten-copper alloy. The stainless steel or tungsten-copper alloy has the advantages of high strength, high specific gravity, high temperature resistance, arc ablation resistance, good electric and thermal conductivity and good processing performance, which may avoid degradation of the performance due to high temperature.

During installation, firstly, the bottom fixture 13 is symmetrically installed on the supporting member 10 of the base 8, secondly, the pretightening member 7 is installed on the supporting member 10, and then the insulating member 3 and the electrode sheet 4 are successively radially installed on the base 8. Since the mass block 6 and the piezoelectric crystal 5 have a groove disposed on a contact surface thereof, the piezoelectric crystal 5 is directly engaged in the groove on the mass block 6 to be mounted in the pretightening member 7 in a unitary manner, when it is installed. The insulating member 3, the electrode sheet 4, the piezoelectric crystal 5 and the mass block 6 on the base 8, and the pretightening member 7 are heated at a high temperature. When the temperature reaches 100° C., the pretightening member 7 starts to shrink, and when the temperature rises to 160° C., the pretightening member 7 reaches a maximum shrinkage, and the bottom fixture 13 is removed. At this time, the insulating member 3, the electrode sheet 4, the piezoelectric crystal 5, and the mass block 6 do not fall in the axial direction of the base 8 due to the pretightening force. The connection between the structural members is rigid, the pretightening member 7 applies a pretightening force to the insulating member 3, the electrode sheet 4, the piezoelectric crystal 5, and the mass block 6, to compress them along the radial direction of the base 8, thereby enhancing the contact stiffness, frequency response characteristics and resonance of the whole structure.

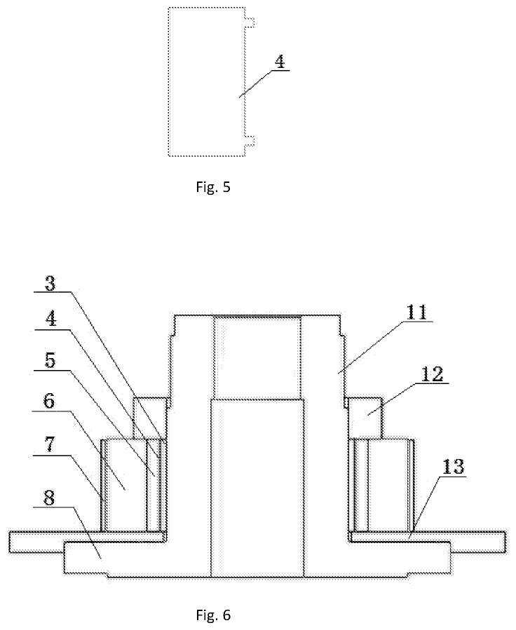

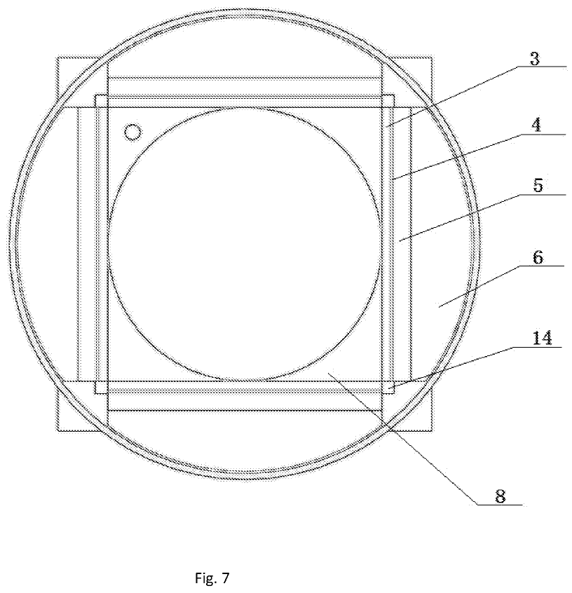

As a specific embodiment, as shown in FIGS. 6-7, the contact surface of the mass block 6 and the piezoelectric crystal 5 is a plane, which is in direct contact with the piezoelectric crystal 5. The mass block has a simple structure, are easy to process and suitable for mass production.

During installation, firstly, the bottom fixture 13 is symmetrically installed on the supporting member 10 of the base 8, secondly, the pretightening member 7 is installed on the supporting member 10, and then the insulating member 3, the electrode sheet 4, the piezoelectric crystal 5, and the mass block 6 are arranged successively from inside to outside and installed on the base 8. The alignment fixture 12 is then installed at the four corners of the base 8 near the top to align the insulating member 3, the electrode sheet 4, the piezoelectric crystal 5, and the mass block 6 installed on the base 8. The top alignment fixture 14 is then installed in the axial direction of the base 8 until the top alignment fixture 14 is stuck on the upper surface of the mass block 6, and the top alignment fixture 14 is an annular frame, which serves as a limit. After the circumference and top of the mass block 6 are aligned, the alignment fixture 12 and the top alignment fixture 14 are removed. The insulating member 3, the electrode sheet 4, the piezoelectric crystal 5 and the mass block 6 on the base 8, and the pretightening member 7 are heated at a high temperature. When the temperature reaches 100° C., the pretightening member 7 starts to shrink, and when the temperature rises to 160° C., the pretightening member 7 reaches a maximum shrinkage, and the bottom fixture 13 is removed. At this time, the insulating member 3, the electrode sheet 4, the piezoelectric crystal 5, and the mass block 6 do not fall in the axial direction of the base 8 due to the pretightening force. The connection between the structural members is rigid, the pretightening member 7 applies a pretightening force to the insulating member 3, the electrode sheet 4, the piezoelectric crystal 5, and the mass block 6, to compress them along the radial direction of the base 8, thereby enhancing the contact stiffness, frequency response characteristics and resonance of the whole structure.

The present application also provides a piezoelectric acceleration sensor shown in FIG. 1, comprising a charge output structure, further comprising a circuit board 9 and a housing 2; wherein, both of the charge output structure and the circuit board are disposed in the housing 2, the circuit board 9 is electrically connected to the piezoelectric element, and has a predetermined distance from the piezoelectric element.

The circuit board 9 amplifies the weak electric charge (voltage) generated by the piezoelectric element after being applied a force to meet the requirements of use. The interval between the circuit board 9 and the piezoelectric element is set at a predetermined distance, so that the circuit board 9 and the piezoelectric element are not in contact with each other, which avoids the influence of the unevenness of the weight of the circuit board 9 on the piezoelectric element, and ensures the frequency response and the stability of the lateral sensitivity of the piezoelectric acceleration sensor.

It is apparent that the above embodiments are merely examples for clarity of illustration, and are not intended to limit the embodiments. Other variations or modifications of the various forms may be made by those skilled in the art in view of the above description. There is no need and no way to present all of the embodiments. The obvious variations or modifications derived therefrom are still within the scope of protection created by the present application.

What is claimed is:

1. A charge output structure, comprising
a base, having an insulating member, a piezoelectric element and a mass block successively arranged from inside to outside and radially sleeved thereon; and
a pretightening member, sleeved on an outer periphery of the mass block and having an annular structure capable of applying a radial pretightening force to the insulating member, the piezoelectric element and the mass block through shrinking with rise of temperature.

2. The charge output structure of claim 1, wherein, the pretightening member is made of nickel-titanium memory alloy.

3. The charge output structure of claim 1, wherein, the piezoelectric element comprises an electrode sheet disposed adjacent to the insulating member and a piezoelectric crystal disposed adjacent to the mass block.

4. The charge output structure of claim 3, wherein,
the base comprises a supporting member and a connecting member disposed on the supporting member;
the insulating member, the electrode sheet, the piezoelectric crystal, the mass block and the pretightening member are sleeved on the connecting member, and a gap is reserved between the insulating member, the electrode sheet, the piezoelectric crystal, the mass block and the pretightening member and the supporting member.

5. The charge output structure of claim 1, wherein, the piezoelectric element and the mass block are both annular structures formed by a plurality of monomers connected together, and the number of the monomers is the integral multiple of 4.

6. The charge output structure of claim 5, wherein, the monomer of the mass block is a sector-shaped monomer, four sector-shaped monomers are symmetrically distributed and sequentially connected to form an annular structure; the monomer of the piezoelectric element is a rectangular monomer, and four rectangular monomers are symmetrically distributed and sequentially connected to form an annular structure.

7. The charge output structure of claim 6, wherein, the mass block and the piezoelectric crystal have a groove disposed on a contact surface thereof, and the piezoelectric crystal is embedded in the groove.

8. The charge output structure of claim 3, wherein, a projection for connecting two adjacent electrode sheets is disposed on the electrode sheets.

9. The charge output structure of claim 1, wherein, the mass block is made of stainless steel or tungsten-copper alloy.

10. A piezoelectric acceleration sensor comprising
a charge output structure according to any one of claim 1,
further comprising a circuit board and a housing;
wherein, both of the charge output structure and the circuit board are disposed in the housing, the circuit board is electrically connected to the piezoelectric element, and has a predetermined distance from the piezoelectric element.

11. The charge output structure of claim 2, wherein, the piezoelectric element comprises an electrode sheet disposed adjacent to the insulating member and a piezoelectric crystal disposed adjacent to the mass block.

12. The charge output structure of claim 11, wherein,
the base comprises a supporting member and a connecting member disposed on the supporting member;
the insulating member, the electrode sheet, the piezoelectric crystal, the mass block and the pretightening member are sleeved on the connecting member, and a gap is reserved between the insulating member, the electrode sheet, the piezoelectric crystal, the mass block and the pretightening member and the supporting member.

13. The charge output structure of claim 11, wherein, a projection for connecting two adjacent electrode sheets is disposed on the electrode sheets.
